(19) United States
(12) Patent Application Publication
(10) Pub. No.: US 2015/0380627 A1
(43) Pub. Date: Dec. 31, 2015

(54) LID ASSEMBLY FOR THERMOPILE TEMPERATURE SENSING DEVICE IN THERMAL GRADIENT ENVIRONMENT

(71) Applicant: Qualcomm Technologies, Inc., San Diego, CA (US)

(72) Inventors: Arvin Emadi, Santa Clara, CA (US); Nicole D. Kerness, Menlo Park, CA (US); Arkadii V. Samoilov, Saratoga, CA (US); Cheng-Wei Pei, Belmont, CA (US); Jerome C. Bhat, Palo Alto, CA (US); Kumar Nagarajan, Cupertino, CA (US); Ken Wang, Milpitas, CA (US)

(21) Appl. No.: 14/580,486

(22) Filed: Dec. 23, 2014

Related U.S. Application Data
(60) Provisional application No. 62/018,092, filed on Jun. 27, 2014.

(51) Int. Cl. H01L 35/32

(52) U.S. Cl. CPC H01L 35/32

(57) ABSTRACT

A temperature sensing device and method for fabrication of the temperature sensing device are described that include a second temperature sensor disposed on and/or in the lid assembly. In an implementation, the temperature sensing device includes a substrate, a ceramic structure disposed on the substrate, a thermopile disposed on the substrate, a first temperature sensor disposed on the substrate, and a lid assembly disposed on the ceramic structure, where the lid assembly includes a base layer, a first filter layer disposed on a first side of the base layer, a first metal layer disposed on a second side of the base layer, a passivation layer disposed on the first metal layer, where the passivation layer includes at least one of a second metal layer, a via, a metal plate, or an epoxy ring, and a second temperature sensor disposed on and/or in the passivation layer.

### BACKGROUND

The present application claims the benefit under 35 U.S.C. §119(e) of U.S. Provisional Application Serial No. 62/018,092, filed Jun. 27, 2014, and titled “TOUCH PANEL DIELECTRIC COVER WITH THROUGH-GLASS VIAS AND METHOD.”U.S. Provisional Application Serial No. 62/018,092 is herein incorporated by reference in its entirety.

A thermopile is an electronic device that converts thermal energy into electrical energy. A thermopile can include several thermocouples coupled together. Thermopiles are used to provide an output voltage in response to temperature as part of a temperature measuring device, where the output voltage is proportional to a local temperature difference (e.g., a temperature gradient).

### SUMMARY

A temperature sensing device and method for fabrication of the temperature sensing device are described that include a first temperature sensor, a second temperature sensor, a resistance temperature detector, a thermopile, and/or a reference thermopile disposed on and/or within the lid assembly. In an implementation, the temperature sensing device includes a substrate, a support structure disposed on the substrate, a thermopile disposed on the substrate, a first temperature sensor disposed on the substrate, and a lid assembly disposed on and/or coupled to the ceramic structure, where the lid assembly includes a base layer, a first filter layer disposed on a first side of the base layer, a first metal layer disposed on a second side of the base layer, a passivation layer disposed on the first metal layer, where the passivation layer includes at least one of a second metal layer, a via, a metal plate, or an epoxy ring, and a second temperature sensor disposed on and/or in the passivation layer.

In an implementation, a process for fabricating the temperature sensing device that employs example techniques in accordance with the present disclosure includes receiving a substrate having a thermopile, a first temperature sensor, and a ceramic structure disposed on the substrate, and placing a lid assembly on the ceramic structure, where the lid assembly includes a base layer, a first filter layer disposed on a first side of the base layer, a first metal layer disposed on a second side of the base layer, a passivation layer disposed on the first metal layer where the passivation layer includes at least one of a second metal layer, a via, a metal plate, or an epoxy ring, and a second temperature sensor disposed on the passivation layer, where the second temperature sensor is exposed to the cavity. The temperature sensing device provides a more accurate calibration and temperature measurement by compensating for a temperature gradient within the device.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### DRAWINGS

The detailed description is described with reference to the accompanying figures. The use of the same reference numbers in different instances in the description and the figures may indicate similar or identical items.

FIG. 1A is a cross section side view illustrating an embodiment of a temperature sensing device that includes at least one temperature sensor with a second temperature sensor included in a lid assembly, in accordance with an example implementation of the present disclosure.

FIG. 1B is a cross section side view illustrating an embodiment of a temperature sensing device that includes a thermopile and a reference thermopile, in accordance with an example implementation of the present disclosure.

FIG. 2 is a flow diagram illustrating an example process for fabricating a temperature sensing device that includes at least one thermopile and/or a temperature sensor with a second temperature sensor included in a lid assembly, such as the temperature sensing device illustrated in FIGS. 1A and 1B.

FIG. 3A is a diagrammatic partial cross-sectional side elevation view illustrating the fabrication of a temperature sensing device, such as the temperature sensing devices shown in FIGS. 1A and 1B in accordance with the process shown in FIG. 2.

FIG. 3B is a diagrammatic partial cross-sectional side elevation view illustrating the fabrication of a temperature sensing device, such as the temperature sensing device shown in FIGS. 1A and 1B in accordance with the process shown in FIG. 2.

### DETAILED DESCRIPTION

### Overview

Temperature sensing devices are becoming more prevalent in portable electronic devices. Thermopiles are often used for temperature sensing in semiconductor and electronic devices. Most temperature sensing devices and systems work well when there is not a thermal gradient in the package. However, many devices create heat internally, which can create an error when calibrating the device and calculating a temperature external to the device. The device and method herein includes placing a temperature sensor on the lid and in the cavity to measure and compensate for the thermal gradient in the package and achieve a high accuracy temperature measurement.

Accordingly, a temperature sensing device and method for fabrication of the temperature sensing device are described that include a second temperature sensor disposed on and/or in the lid assembly or multiple thermopiles. In an implementation, the temperature sensing device includes a substrate, a ceramic structure disposed on the substrate, a thermopile disposed on the substrate, a first temperature sensor disposed on the substrate, and a lid assembly disposed on the ceramic structure, where the lid assembly includes a base layer, a first filter layer disposed on a first side of the base layer, a first metal layer disposed on a second side of the base layer, a passivation layer disposed on the first metal layer, where the passivation layer includes at least one of a second metal layer, a via, a metal plate, or an epoxy ring, and a second temperature sensor disposed on and/or in the passivation layer. In another implementation, the temperature sensing device can include a reference thermopile instead of a surface mountable first temperature sensor or a second temperature sensor. In implementations, a process for fabricating the temperature sensing device that employs example techniques in accordance with the present disclosure includes receiving a substrate having a thermopile, a first temperature sensor, and a ceramic structure disposed on the substrate, and placing a lid assembly on the ceramic structure, where the lid assembly includes a base layer, a first filter layer disposed on a first side of the base layer, a first metal layer disposed on a second side of the base layer, a passivation layer disposed on the first metal layer, where the passivation layer includes at least one of a second metal layer, a via, a metal plate, or an epoxy ring, and a second temperature sensor disposed on the passivation layer, where the second temperature sensor is exposed to the cavity.

The temperature sensing device disclosed herein provides improved sensitivity by placing the second temperature sensor on the lid assembly as well as in the cavity or including a reference thermopile. A second temperature sensor can allow temperature gradient measurement within the semiconductor package when the temperature of the semiconductor package is measured.

### Example Implementations

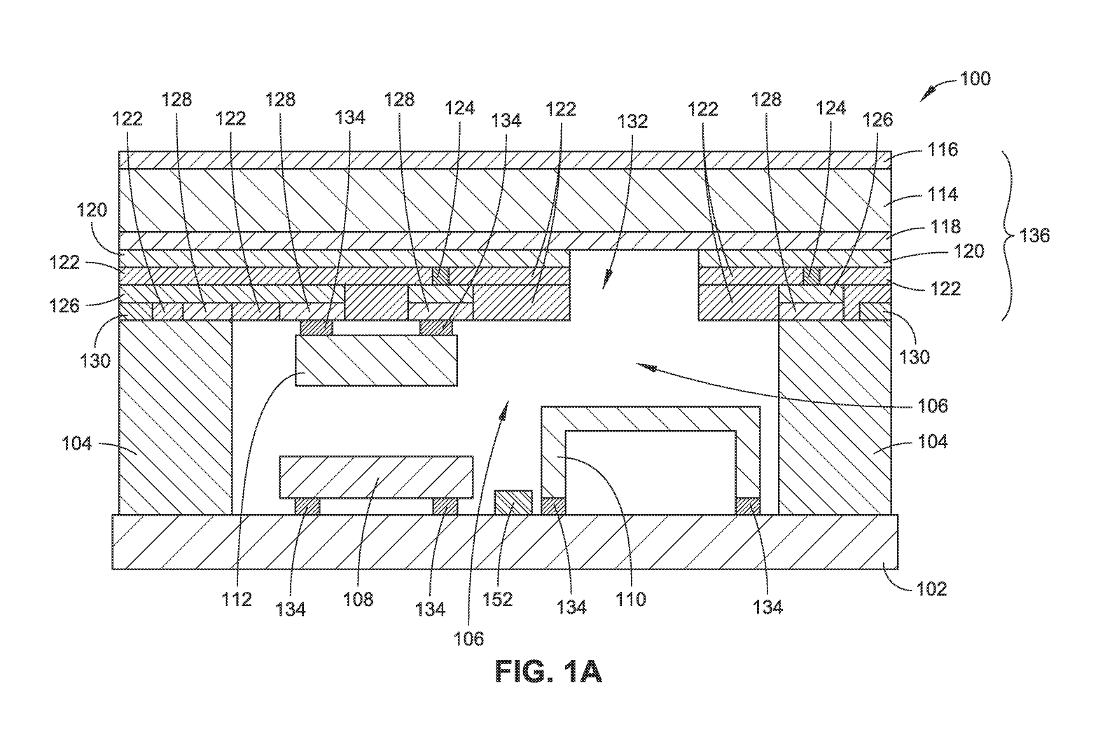

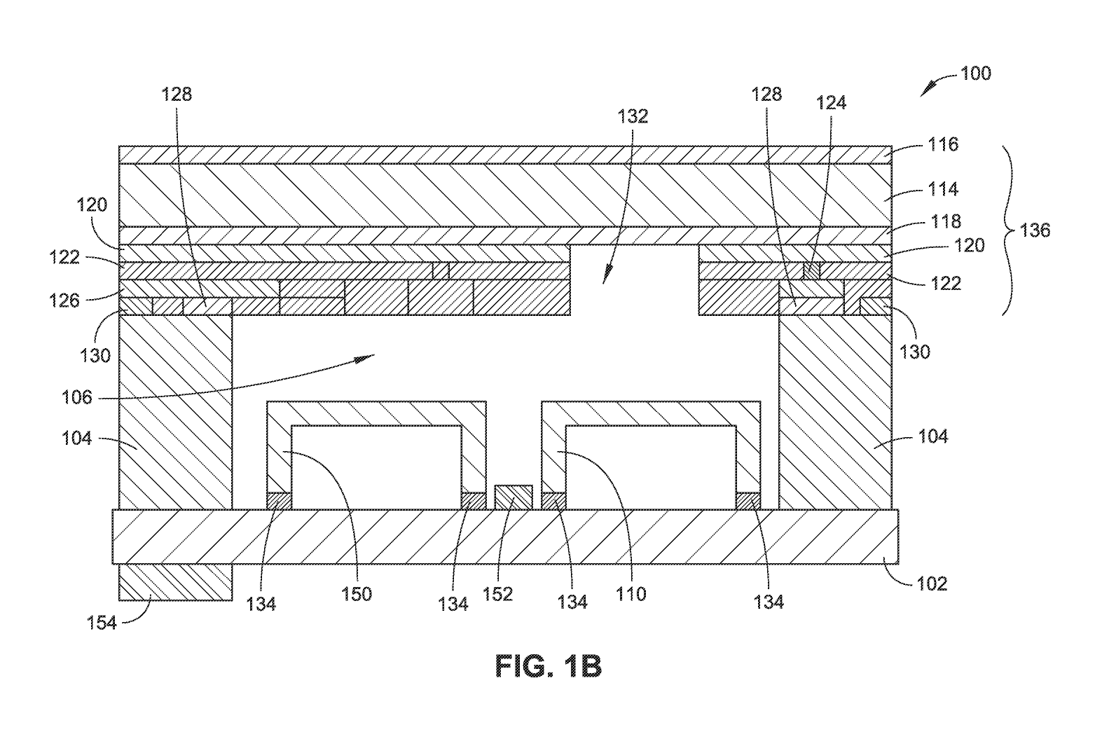

FIGS. 1A and 1B illustrate a temperature sensing device 100 in accordance with an example implementation of the present disclosure. As shown in FIGS. 1A and 1B, the temperature sensing device 100 includes a substrate 102. In some implementations, a substrate 102 can include a printed circuit board. A printed circuit board can include a substrate that is configured to mechanically support and electrically connect electronic components using conductive tracks, pads, and other features etched from copper sheets laminated onto a non-conductive substrate. In one embodiment, the substrate 102 includes a laminated printed circuit board configured to mechanically support a support structure 104, and at least one surface mount device. It is contemplated that substrate 102 can include other materials, such as a silicon-based substrate. In another specific embodiment, the substrate 102 can include a silicon substrate, such as a segmented silicon wafer. The substrate 102 can be configured to receive and/or be coupled to other device components as disclosed below. Additionally, the substrate 102 can include electrical interconnections, such as a redistribution layer and/or other metal routing.

As illustrated in FIGS. 1A and 1B, the temperature sensing device 100 includes a support structure 104 disposed on the substrate 102. In implementations, the support structure 104 can at least partially define a cavity 106, in which is disposed at least one temperature sensor (e.g., first temperature sensor 108, second temperature sensor 112, etc.), or a thermopile 110, etc. In one implementation, the support structure 104 can include a ceramic structure, which may be formed from a photodefinable (photo-structurable) glass. In some embodiments, photodefinable glass can include sensitizers that allow unique anisotropic 3D features to be formed through exposure to ultraviolet (UV) light and subsequent baking and etching of ceramic formed after exposure to the UV light. In one specific embodiment, the substrate 102 may include a photodefinable glass layer where the photodefinable glass layer is optically transparent, chemically inert, and thermally stable up to approximately 450° C. In this embodiment, the photodefinable glass layer can be exposed to light, baked, and etched to form a support structure 104 suitable for defining cavity 106 and supporting lid assembly 136. During the light exposure and etching processes, different features may be formed, such as a hole (e.g., for forming a through glass via) and/or a wall. At least some of these features can be configured to facilitate electrical interconnections (e.g., vias, a redistribution layer, metal lines, etc.) In a specific embodiment, the photodefinable glass layer can be converted to a ceramic state and left un-etched, for example, to form a light isolation component. In other specific embodiments, the support structure 104 can include other materials, such as metal materials, metallic alloys, glass, SiO₂, AN, and/or Al₂O₃.

As illustrated in FIGS. 1A and 1B, the temperature sensing device 100 includes a thermopile 110 disposed on the substrate 102. In implementations, a thermopile 110 can include an electronic device that converts thermal energy into electrical energy. A thermopile can include several thermocouples or temperature sensors connected in series or in parallel. In one embodiment, the thermopile 110 can be disposed on and electrically coupled to the surface of the substrate 102, for example, using electrical interconnects and/or a die attach 134 (e.g., Ag die attach epoxy). In a specific embodiment, thermopile 110 is attached to the surface of substrate 102 using a die attach epoxy such that thermopile 110 is configured to be disposed below an aperture 132 (between the aperture 132 and the substrate 102) in lid assembly 136. In this embodiment, the thermopile 110 can be configured to receive and/or detect electromagnetic energy (e.g., energy from a human) external to the temperature sensing device 100, which can be converted to a temperature.

The temperature sensing device 100 may include a first temperature sensor 108 disposed on the substrate 102. In one implementation, a first temperature sensor 108 can include a thermocouple. A thermocouple may include a temperature-measuring device including two dissimilar conductors that contact each other at one or more points and produces a voltage when the temperature of one of the points differs from the reference temperature at other parts of the circuit. Other examples of the first temperature sensor 108 can include a resistance temperature detector (RTD), a resistor, a thermistor, and/or a negative temperature coefficient (NTC) thermistor. It is contemplated that the first temperature sensor 108 can include other types of temperature sensors. The first temperature sensor 108 can be disposed on the substrate 102 (the hot side of the temperature sensing device 100) and can be configured to measure the temperature of the substrate 102 and/or the energy created within the temperature sensing device 100.

As shown in FIGS. 1A and 1B, the temperature sensing device 100 may include a resistance temperature detector 152. The resistance temperature detector 152 may be disposed on and/or coupled to the substrate 102 and adjacent to the thermopile 110, a reference thermopile 150, and/or the first temperature sensor 108. A resistance temperature detector (RTD) 152 can include a sensor used to measure a temperature by correlating the resistance of the RTD element with varying temperature. Additionally, the resistance temperature detector 152 can be electrically coupled to the other components of the temperature sensing device 100 (e.g., an ASIC 154, the thermopile 110, etc.). In a specific embodiment, the resistance temperature detector 152 can be configured to provide a temperature for calibration of the temperature sensing device 100.

As shown in FIG. 1B, the temperature sensing device 100 can include a reference thermopile 150. In some embodiments, the temperature sensing device 100 does not include a first temperature sensor 108 and/or a second temperature sensor 112, but instead includes the thermopile 110, the resistance temperature detector 152, and the reference thermopile 150. In embodiments, the reference thermopile 150 can be disposed such that it is not proximate and/or exposed to light and/or energy passing through the aperture 132. The reference thermopile 150 can detect electromagnetic (e.g., infrared) radiation associated with the components within the sensor package 100 while the thermopile 110 can detect electromagnetic (e.g., infrared) radiation associated with the components within the temperature sensing device 100 and outside the temperature sensing device 100. In implementations, a signal from the thermopile 110 can be subtracted (or compared to) from a signal from the reference thermopile sensor 113 in order to calibrate the temperature sensing device 100 and configure the temperature sensing device 100 to detect an accurate temperature. In some embodiments, the subtraction and/or comparison may occur within a digital domain or an analog domain.

As shown in FIGS. 1A and 1B, the temperature sensing device 100 includes a lid assembly 136 disposed on and coupled to the support structure 104. The lid assembly 136, the substrate 102, and the support structure 104 define a cavity 106, which can house the thermopile 110, reference thermopile 150, and/or the first temperature sensor 108. The lid assembly 136 can be electrically interconnected with the substrate 102 and other electrical components associated with the substrate 102 (e.g., first temperature sensor 108, thermopile 110, ASIC 154, etc.).

In embodiments, the lid assembly 136 can include a base layer 114. The base layer 114 may include a material is configured to provide mechanical support for other layers and functional devices as a part of the lid assembly 114. In one specific embodiment, the base layer 114 can include a layer of silicon. The base layer 114 can be configured to allow energy and/or light to pass through an aperture 132. In some embodiments, the aperture 132 can include a lens. In an embodiment, the base layer 114 includes a first filter layer 116 disposed on a first side (e.g., side distal from the substrate 102) of the base layer 114. The first filter layer 116 can include, for example, a light filter, an anti-reflective layer, and/or other material. In one specific embodiment, the first filter layer 116 can include an anti-reflective film. In another specific embodiment, the first filter layer 116 can include an ultraviolet light filter. It is contemplated that other filter types and/or light-altering layers can be utilized alone or in combination as a first filter layer 116. In some additional embodiments, a second filter layer 116 may be formed on and/or disposed on a second side (e.g., side closest to the substrate 102) of the base layer 114. In these embodiments, the second filter layer 116 can include a light filter and/or an anti-reflective coating as disclosed above. In a specific embodiment, the second filter layer 116 can include a low emissivity filter layer configured to minimize the effect of the first temperature sensor 108 and/or another filter layer with a known emissivity.

A first metal layer 120 can be disposed on the base layer 114 and/or the second filter layer 118, as illustrated in FIGS. 1A and 1B. In some implementations, the first metal layer 120 can at least partially function as an electrical interconnection between electrical components in the temperature sensing device 100 (e.g., between the thermopile 110, a first temperature sensor 108 and/or a second temperature sensor 112). In one specific embodiment, the first metal layer 120 includes titanium. In another specific embodiment, the first metal layer 120 can include titanium nitride. It is contemplated that other metals and/or conductive materials may be used. The first metal layer 120 can be formed using deposition techniques, such as physical vapor deposition, sputtering, etc. Additionally, an aperture 132 may be formed in and/or partially defined by the first metal layer 120. The aperture 132 can function to set the field-of-view (FOV) of the temperature sensing device 100.

At least one passivation layer 122 may be formed on the first metal layer 120. The passivation layer 122 may include an electrical insulator that functions as an insulator and/or a protective layer between metal layers and other components of the temperature sensing device 100. In one embodiment, the passivation layer 122 can include a layer or layers of silicon dioxide (SiO₂) formed on the first metal layer 120. In another embodiment, the passivation layer 122 may include a thin film (e.g., benzocyclobutene (BCB), etc.). In implementations, the passivation nlayer 122 can include one or more material layers that may include the same or different dielectric materials. In implementations, the passivation layer 122 can be formed and/or deposited on the first metal layer 120 using deposition (e.g., physical vapor deposition, chemical vapor deposition, spin coating, etc.) and/or etching techniques. In the example shown in FIGS. 1A and 1B, the passivation layer 122 can be deposited and etched such that an aperture 132 is formed in and/or at least partially defined by the passivation layer 122. Additionally, FIG. 1 further shows the passivation layer 122 etched to form at least one via 124 and other etched portions where another layer can be deposited (e.g., a second metal layer 126, which may function as an electrical interconnection). In this example, the aperture 132 can be aligned such that light/energy from outside of the temperature sensing device 100 can pass through the lid assembly 136 and light/energy from inside the temperature sensing device 100 may also pass through the base layer 114.

In some implementations, at least one via 124 may be formed in the passivation layer 122. The via(s) 124 can include a through-hole electrical connection between at least two different layers in the temperature sensing device 100 and/or lid assembly 136 (e.g., a vertical connection between the first metal layer 120 and the second metal layer 126). Some examples of vias can include a through via, a blind via, a buried via, etc. The via(s) 124 may be back filled with an electrical conductor, such as gold, tungsten, copper, etc., in order to form the electrical connection. In implementations, the via(s) 124 can be formed using deposition, mask, and etching fabrication techniques.

In embodiments, a second metal layer 126 may be formed on and/or in a portion of the passivation layer 122. The second metal layer 126 can be deposited using deposition and etching fabrication techniques similar to the other metal layers disclosed herein. In an implementation, a second metal layer 126 can be deposited such that it functions as an electrical interconnection between different components and/or different conducting layers within the temperature sensing device 100 (e.g., a temperature sensor and an electrical connection in the support structure 104). In one specific instance as illustrated in FIG. 1A, a portion of the second metal layer 126 can at least partially serve as an electrical interconnection between the second temperature sensor 112 and a via 124 electrically coupled to the first metal layer 120. In an additional embodiment also shown in FIG. 1A, the second metal layer 126 can function as an electrical interconnection between the second temperature sensor 112 and another component (e.g., an ASIC 154) of the temperature sensing device 100. The second metal layer 126 can include at least one metal. In one specific embodiment, the second metal layer 126 can include a layer of gold. In this embodiment, the gold second metal layer 126 functions as an electrical connector. It is contemplated that other metals, alloys, and/or conductive materials can be used.

As shown in FIG. 1A, a metal plate 128 can be deposited and/or formed on the second metal layer 126 within the lid assembly 136. In implementations, the metal plate 128 can function as a good electrical conductor and/or as a good adhering agent between the electrical interconnections of a second temperature sensor 112 and the electrical interconnections within the lid assembly 136 (e.g., the second metal layer 126, etc.). The metal plate 128 can be deposited and etched using deposition, masking, and etching techniques. In one specific embodiment, the metal plate 128 can include a gold metal plate 128. It is contemplated that the metal plate 128 may include other metals (e.g., copper, aluminum, etc.).

In some embodiments, a second temperature sensor 112 may be coupled to the lid assembly 136. In one specific instance, the second temperature sensor 112 can include a thermocouple. In the embodiment shown in FIG. 1A, the second temperature sensor 112 can be coupled to the metal plate(s) 128 on the lid assembly 136 using a die attach 134 (e.g., an Ag die attach epoxy) or other bonding material. In some specific embodiments, the second temperature sensor 112 can be electrically coupled to the lid assembly 136 using electrical connections, such as a leadframe and/or wirebonding. It is contemplated that other electrical connections may be utilized. In the embodiment illustrated in FIG. 1A, the second temperature sensor 112 can be coupled to a surface of the lid assembly 136 and extend into the cavity 106. In another embodiment, the second temperature sensor 112 can be formed as a portion of and integrated into the lid assembly 136. In this embodiment, the second temperature sensor 112 can be formed in and/or as a part of the base layer 114 and/or passivation layer 122 such that the second temperature sensor 112 does not substantially extend into the cavity 106. Placing the second temperature sensor 112 on and/or as a portion of the lid assembly 136 can allow for measurement of a temperature gradient within the temperature sensing device 100 and compensate for the temperature gradient to obtain a high accuracy temperature measurement.

Referring to FIGS. 1A and 1B, an application-specific integrated circuit 154 (ASIC) may be employed to generate a digital signal representing the electromagnetic radiation detected by the thermopile 110, the reference thermopile 150, the first temperature sensor 108, the second temperature sensor 112, and/or the resistor temperature detector 152. For example, the application-specific integrated circuit 154 may include a module that is electrically connected to the temperature sensing device 100 to receive the electrical signals generated by the thermopile 110, the reference thermopile 150, the resistance temperature detector 152, the first temperature sensor 108, and/or the second temperature sensor 112 in response to the electromagnetic radiation occurring within the limited spectrum of wavelengths.

In implementations, the circuitry within the application-specific integrated circuit 154 may include analog-to-digital converter circuitry, programmable-gain amplifier (PGA) circuitry, fixed-gain amplifier circuitry, combinations thereof, or the like. The application-specific integrated circuit 154 can be configured to receive the electrical signal from the thermopile 110, the electrical signal from the resistance temperature detector 152, the reference thermopile 150, the first temperature sensor 108, and/or the second temperature sensor 112 to generate a signal representing a temperature associated with an object outside the temperature sensing device 100. In an embodiment, the application-specific integrated circuit 154 can be configured to compare (e.g., subtract, remove, add, etc.) the electrical signal that is common to both electrical signals (e.g., the electrical signal that represents the electromagnetic radiation associated with the package) with the electrical signal from the thermopile 110 and generate a signal that represents a temperature associated with an object external the temperature sensing device 100 (e.g., a human finger, ambient air temperature, etc.). In one implementation, the application-specific integrated circuit 154 may store calibration parameters to generate corresponding digital calculations.

The application-specific integrated circuit 154 may be configured to utilize a calibration protocol associated with the temperature sensing device 100. The application-specific integrated circuit 154 can compare the electrical signal that is common to both electrical signals to generate an electrical signal representing an error signal associated with the thermopile 110, the reference thermopile 150, the resistance temperature detector 152, the first temperature sensor 108, and/or the second temperature sensor 112. The application-specific integrated circuit 154 may then be calibrated for accurate temperature measurement based upon utilizing the error signal. This calibration protocol may be performed in-situ or during initial factory calibration.

### Example Processes

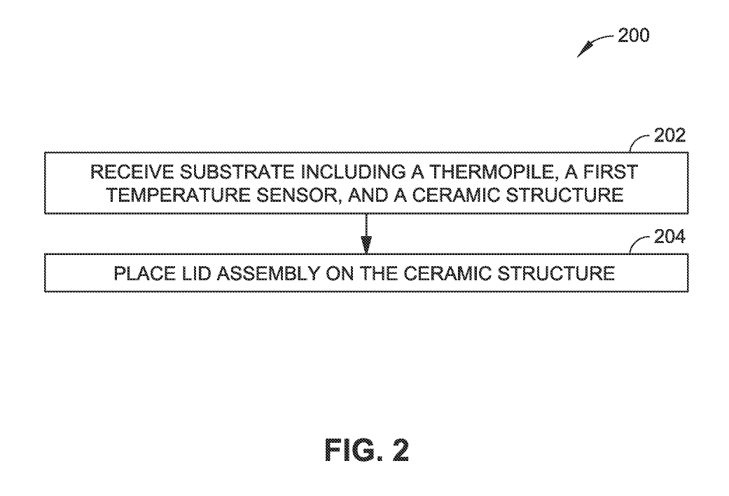

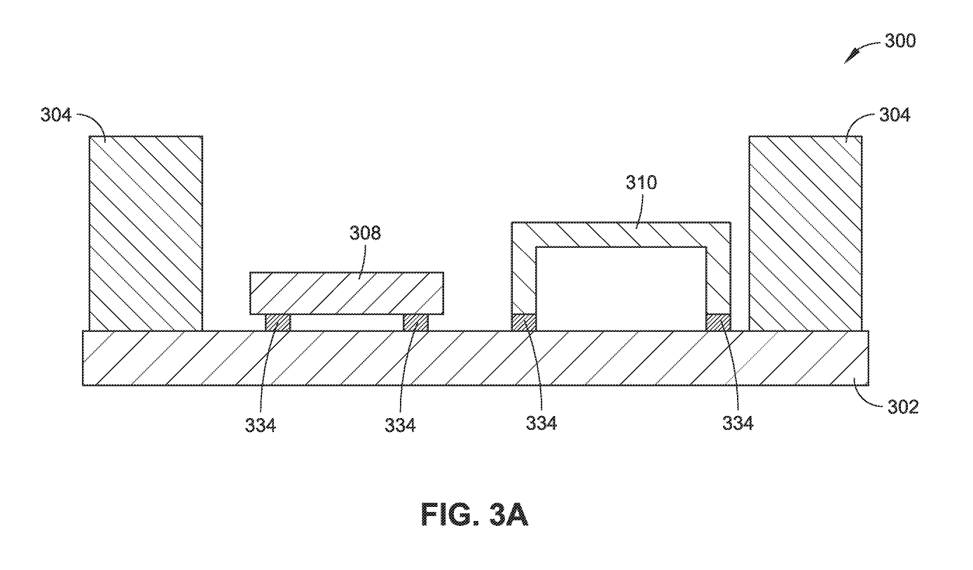

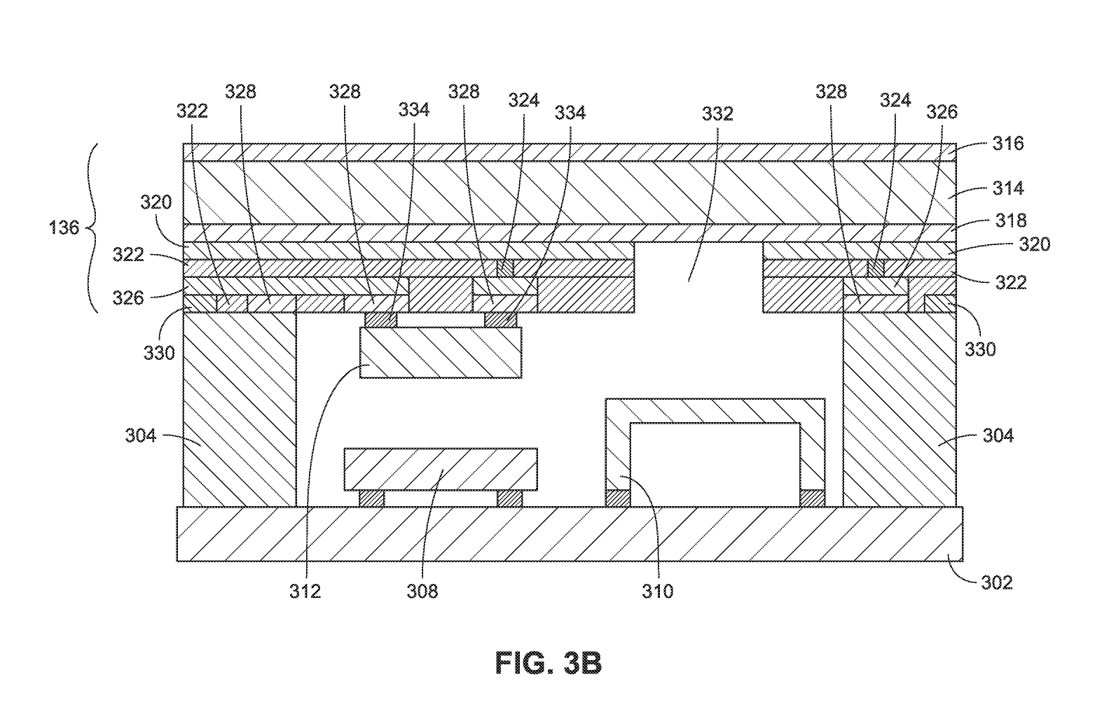

FIG. 2 illustrates an example process 200 that employs techniques to fabricate temperature sensing devices, such as the temperature sensing device 100 shown in FIGS. 1A and 1B, showing section 300. FIGS. 3A through 3B illustrate a section 300 of a temperature sensing device during fabrication (such as the temperature sensing device 100 shown in FIGS. 1A through 1B).

In the process 200 illustrated, a substrate including a thermopile, a first temperature sensor, and a ceramic structure is received (Block 202). In some implementations, receiving a substrate 302 can include receiving a printed circuit board, for example, including a first temperature sensor 308 and a thermopile 310 both coupled to the printed circuit board using, for example, a die attach adhesive 334. In another implementation, receiving a substrate 102 can include receiving a substrate 102 can include receiving a substrate 102 including a thermopile 310 and a reference thermopile 150. Additionally, receiving the substrate 302 includes receiving a substrate 302 having a support structure 304 formed thereon. In implementations, the support structure 304 can be formed from a photodefinable (photo-structurable) glass previous to receiving the substrate 302. The substrate 302 can generally be configured to accept a lid assembly 336 in order to form a temperature sensing device 100.

Then, a lid assembly is placed on the support structure disposed on the substrate (Block 204). In implementations, placing a lid assembly 336 on the support structure 308 includes placing a lid assembly 336 where the lid assembly 336 includes at least one of a base layer 314, a first filter layer 116, a second filter layer 318, a first metal layer 320, a passivation layer 322, a second metal layer 326, at least one via 324, a metal plate 328, an epoxy ring 330, and/or a second temperature sensor 312 that is coupled with and/or integrated into the base layer 314 of the lid assembly 336. Placing the lid assembly 336 can include using pick-and-place and/or surface mount technologies and an adhesive, such as a die attach epoxy (e.g., epoxy ring 330), for example, to the top surface (e.g., the side distal from the substrate 302) of the support structure 304. When an epoxy ring 330 is included, it may serve as a hermetic seal for the cavity 106 and/or temperature sensing device 100. The lid assembly 336 may be placed such that an aperture 332 formed in the lid assembly 336 can be aligned with the thermopile 310 disposed on the substrate 302, but are not the reference thermopile 150 and/or first temperature sensor 308 and second temperature sensor 312. In implementations, placing the lid assembly 336 may form a cavity 306 at least partially defined by the lid assembly 336, the support structure 304, and the substrate 302. In embodiments, including the second temperature sensor 312 with the lid assembly 336 as well as in and/or exposed to the cavity 306 (or including a reference thermopile 150) allows a temperature gradient within the temperature sensing device 100 to be measured and compensated for when the temperature of an object is measured.

### Conclusion

Although the subject matter has been described in language specific to structural features and/or process operations, it is to be understood that the subject matter defined in the appended claims is not necessarily limited to the specific features or acts described above. Rather, the specific features and acts described above are disclosed as example forms of implementing the claims.

What is claimed is:

1. A temperature sensing device, comprising:
a substrate;
a support structure disposed on the substrate;
a thermopile disposed on the substrate;
a first temperature sensor disposed on the substrate;
a resistance temperature detector disposed on the substrate; and
a lid assembly disposed on the support structure, where the lid assembly, the substrate, and the support structure define a cavity, where the lid assembly includes
a base layer;
a first filter layer disposed on a first side of the base layer;
a first metal layer disposed on a second side of the base layer;
a passivation layer disposed on the first metal layer, where the passivation layer includes at least one of a second metal layer, a via, a metal plate, or an epoxy ring, and the passivation layer and the first metal layer define an aperture; and
a second temperature sensor disposed on the passivation layer, where the second temperature sensor is exposed to the cavity.

2. The temperature sensing device of claim 1, wherein the support structure includes a ceramic support structure.

3. The temperature sensing device of claim 1, wherein the base layer includes a silicon layer.

4. The temperature sensing device of claim 1, wherein the aperture is disposed over the thermopile.

5. The temperature sensing device of claim 1, wherein the epoxy ring includes a silver die attach epoxy.

6. The temperature sensing device of claim 1, further comprising:
a second filter layer disposed on a second side of the base layer between the base layer and the first metal layer.

7. The temperature sensing device of claim 1, further comprising:
an application specific integrated circuit that is electrically coupled to at least one of the thermopile, the first temperature sensor, or the second temperature sensor.

8. The temperature sensing device of claim 1, further comprising:
a lens disposed over the aperture, where the lens is configured to collimate electromagnetic radiation occurring in the limited spectrum of wavelengths incident upon the lens and to transmit the collimated electromagnetic radiation to the thermopile.

9. A temperature sensing device, comprising:
a substrate;
a support structure disposed on the substrate;
a thermopile sensor disposed on the substrate;
a reference thermopile sensor disposed on the substrate;
a resistance temperature detector disposed on the substrate between the thermopile sensor and the reference thermopile sensor; and
a lid assembly disposed on the support structure, where the lid assembly, the substrate, and the support structure defines a cavity, where the lid assembly comprises
a base layer;
a first filter layer disposed on a first side of the base layer;
a first metal layer disposed on a second side of the base layer; and
a passivation layer disposed on the first metal layer, where the passivation layer includes at least one of a second metal layer, a via, a metal plate, or an epoxy ring, and the passivation layer and the first metal layer define an aperture.

10. The temperature sensing device of claim 9, wherein the support structure includes a ceramic support structure.

11. The temperature sensing device of claim 9, wherein the base layer includes a silicon layer.

12. The temperature sensing device of claim 9, wherein the aperture is disposed over the thermopile sensor.

13. The temperature sensing device of claim 9, wherein the epoxy ring includes a silver die attach epoxy.

14. The temperature sensing device of claim 9, further comprising:
a second filter layer disposed on a second side of the base layer between the base layer and the first metal layer.

15. The temperature sensing device of claim 9, further comprising:
an application specific integrated circuit that is electrically coupled to at least one of the thermopile, the first temperature sensor, or the reference thermopile.

16. The temperature sensing device of claim 15, wherein the thermopile sensor and the reference thermopile sensor are integrated with the same integrated circuit.

17. A process, comprising:
receiving a substrate having at least one of a thermopile, a reference thermopile, or a first temperature sensor, and a support structure disposed on the substrate; and
placing a lid assembly on the support structure, where the lid assembly includes
a base layer;
a first filter layer disposed on a first side of the base layer;
a first metal layer disposed on a second side of the base layer; and
a passivation layer disposed on the first metal layer, where the passivation layer includes at least one of a second metal layer, a via, a metal plate, or an epoxy ring;
where the base layer and the passivation layer define an aperture.

18. The process of claim 17, wherein the support structure includes a ceramic support structure.

19. The process of claim 17, wherein the aperture is disposed over the thermopile sensor.

20. The process of claim 17, wherein the lid assembly includes a second temperature sensor disposed on the passivation layer, where the second temperature sensor is exposed to a cavity defined by the lid assembly, the support structure, and the substrate.
